(19) United States
(12) Patent Application Publication
(10) Pub. No.: US 2019/0161860 A1
(43) Pub. Date: May 30, 2019

(54) METHOD OF CHANGING OXIDATION LEVEL OF GRAPHENE OXIDE, WAFER AND OPTICAL COATING

(71) Applicant: GOLD CARBON CO., LTD., Taoyuan City (TW)

(72) Inventor: Chien-Te HSIEH, New Taipei City (TW)

(73) Assignee: GOLD CARBON CO., LTD., Taoyuan City (TW)

(21) Appl. No.: 15/892,621

(22) Filed: Feb. 9, 2018

Related U.S. Application Data
(60) Provisional application No. 62/591,082, filed on Nov. 27, 2017.

(51) Int. Cl. C23C 16/455; C23C 16/40

(52) U.S. Cl. CPC C23C 16/45534; C23C 16/45525; C23C 16/40

(57) ABSTRACT

A method of changing an oxidation level of graphene oxide includes the steps of: providing a graphene oxide including functional groups containing oxygen; and implementing an atomic layer chemical process to perform an oxygen stripping reaction or an oxygen increasing reaction of the graphene oxide with a reaction gas. A wafer including graphene oxide treated by the method and an optical coating including graphene oxide quantum dots treated by the method are disclosed.

### CROSS-REFERENCE TO RELATED APPLICATIONS

This non-provisional application claims priority under 35 U.S.C. § 119(a) on Patent Application No(s). 62/591,082 filed in United States on Nov. 11, 2017, the entire contents of which are hereby incorporated by reference.

### TECHNICAL FIELD

The present disclosure relates to a wafer, an optical coating, and a method of changing the oxidation level of graphene oxide, more particularly to a method of changing the oxidation level of graphene oxide by atomic layer deposition equipment, as well as a wafer and an optical coating including graphene oxide treated by the aforementioned method.

### BACKGROUND

Nanocarbon materials, such as nanotube and graphene, have attracted extensive attention in a variety of technological applications because of its unique molecular structure and extraordinary physical properties. Especially grapheme it is a material with potential applications in nanoelectronic components and optical components since it has many unusual properties such as massless Dirac fermions, the anomalous quantum Hall effect, and high charge carrier mobility. However, pure graphene is a zero band gap semiconductor because its conduction and valence bands meet at the Dirac points, which causes pure graphene to be difficult to be applied to various applications.

In conventional techniques, the modification of graphene is accomplished by quantum confinement, doping or symmetry breaking, so that the band gap of graphene is able to be adjusted to change its electrical and optical properties. For example, the graphene is modified by bromine vapor or iodine vapor to generate functional groups containing bromine or iodine. The graphene is modified by photoexciting ammonia molecules adsorbed on the graphene to generate functional groups containing nitrogen. The graphene is treated by photolithography and etching processes to generate band-shaped graphene holes array, thereby changing the band gap of graphene.

### SUMMARY

According to one aspect of the present disclosure, a method of changing an oxidation level of graphene oxide includes the steps of: providing a graphene oxide including functional groups containing oxygen; and implementing an atomic layer chemical process to perform an oxygen stripping reaction or an oxygen increasing reaction of the graphene oxide with a reaction gas. The atomic layer chemical process includes 10 or more cycles of the oxygen stripping reaction or 10 or more cycles of the oxygen increasing reaction.

According to another aspect of the present disclosure, a wafer includes graphene oxide treated by the aforementioned method of changing the oxidation level of graphene oxide.

According to still another aspect of the present disclosure, an optical coating comprising graphene oxide quantum dots treated by the aforementioned method of changing the oxidation level of graphene oxide.

### BRIEF DESCRIPTION OF THE DRAWINGS

The present disclosure will become more fully understood from the detailed description given hereinbelow and the accompanying drawings which are given by way of illustration only and thus are not intending to limit the present disclosure and wherein:

FIG. 1 is a schematic view of changing the oxidation level of graphene oxide in atomic layer deposition equipment according to one embodiment of the present disclosure;

FIG. 2 is a flowchart of a method of changing the oxidation level of graphene oxide according to one embodiment of the present disclosure;

FIG. 3 is a chart of the interlayer distance between each adjacent graphene layer in a graphene oxide, which is treated by the method in FIG. 2, versus cycles of an oxygen stripping reaction;

FIG. 4 is a chart of the number of functional groups containing oxygen in the graphene oxide, which is treated by the method in FIG. 2, versus cycles of an oxygen stripping reaction;

FIG. 5 is a chart of the band gap of the graphene oxide, which is treated by the method in FIG. 2, versus the oxygen-carbon atomic ratio of the graphene oxide;

FIG. 6 is a chart of the electrical resistivity of the graphene oxide, which is treated by the method in FIG. 2, versus cycles of an oxygen stripping reaction;

FIG. 7 is a chart of the electrical conductivity of the graphene oxide, which is treated by the method in FIG. 2, versus cycles of an oxygen stripping reaction;

FIG. 8 is a chart showing intensity and wavelength of the photoluminescence response of the graphene oxide which is treated by the method in FIG. 2;

FIG. 9 is a schematic view of changing the oxidation level of graphene oxide in atomic layer deposition equipment according to another embodiment of the present disclosure;

FIG. 10 is a flowchart of a method of changing the oxidation level of graphene oxide according to another embodiment of the present disclosure;

FIG. 11 is a chart of the interlayer distance between each adjacent graphene layer in a graphene oxide, which is treated by the method in FIG. 10, versus cycles of an oxygen increasing reaction;

FIG. 12 is a chart of the number of functional groups containing oxygen in the graphene oxide, which is treated by the method in FIG. 10, versus cycles of an oxygen increasing reaction;

FIG. 13 is a chart of the oxygen-carbon atomic ratio of the graphene oxide, which is treated by the method in FIG. 10, versus cycles of an oxygen increasing reaction;

FIG. 14 is a chart of the band gap of the graphene oxide, which is treated by the method in FIG. 10, versus the oxygen-carbon atomic ratio of the graphene oxide;

FIG. 15 is a chart of the electrical resistivity of the graphene oxide, which is treated by the method in FIG. 10, versus cycles of an oxygen increasing reaction;

FIG. 16 is a chart of the electrical conductivity of the graphene oxide, which is treated by the method in FIG. 10, versus cycles of an oxygen increasing reaction; and

FIG. 17 is a chart showing intensity and wavelength of the photoluminescence response of the graphene oxide which is treated by the method in FIG. 10.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

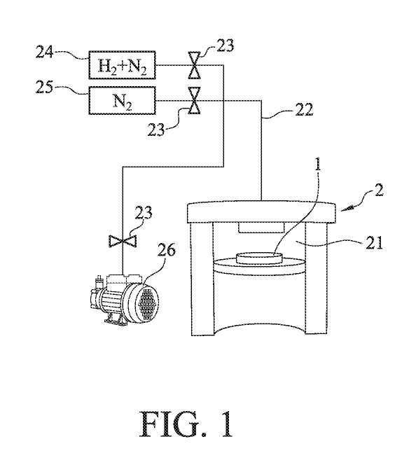

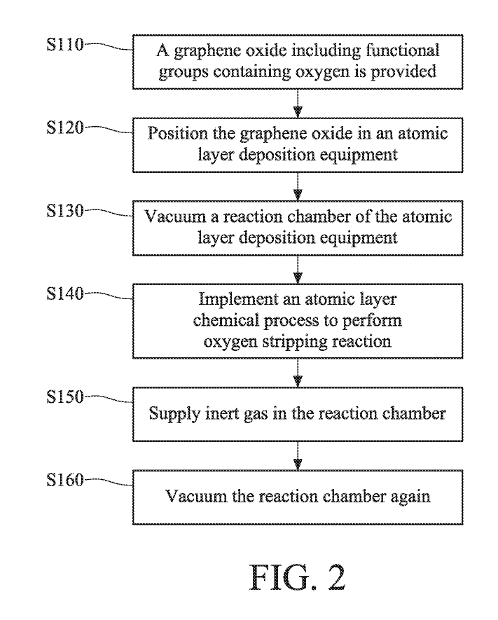

Please refer to FIG. 1 and FIG. 2. FIG. 1 is a schematic view of changing the oxidation level of graphene oxide in atomic layer deposition equipment according to one embodiment of the present disclosure. FIG. 2 is a flowchart of a method of changing the oxidation level of graphene oxide according to one embodiment of the present disclosure. In this embodiment, a method of changing the oxidation level of graphene oxide is to perform an oxygen stripping reaction of a graphene oxide sheet or a graphene oxide powder in atomic layer deposition equipment.

The method of changing the oxidation level of graphene oxide includes steps S110 to S160. In step S110, a graphene oxide including functional groups containing oxygen is provided. In this embodiment, a graphene oxide 1 including hydroxyl groups (C—OH), carbonyl groups (C═O) and carboxyl groups (COOH) is provided. The graphene oxide 1, for example, is a graphene oxide powder obtained by performing a reduction reaction of a graphene oxide, which is produced by conventional Hummers method, with hydrogen at a temperature of 400° C., and the mass of the graphene oxide 1 is from 0.5 grams (g) to 1.0 g. It is worth noting that the type of functional group containing oxygen, the mass of graphene oxide and the oxidation level of graphene oxide in the present disclosure are not limited by the above.

In step S120, the graphene oxide is positioned in the atomic layer deposition equipment. In this embodiment, an atomic layer deposition equipment 2 includes a reaction chamber 21, a pipe system 22, a plurality of valves 23, a first gas tank 24, a second gas tank 25 and a vacuum pump 26. The reaction chamber 21 is configured to accommodate the graphene oxide 1. The reaction chamber 21, the first gas tank 24, the second gas tank 25 and the vacuum pump 26 are connected to each other through the pipe system 22. The valves 23 are disposed on the pipe system 22 in order to control the state of connection between the reaction chamber 21 and either the first gas tank 24, the second gas tank 25 or the vacuum pump 26. The first gas tank 24 is configured to store reaction gas, and the second gas tank 25 is configured to store inert gas.

In step S130, the reaction chamber of the atomic layer deposition equipment is vacuumed. In detail, the valve 23 between the reaction chamber 21 and the vacuum pump 26 is opened to allow the vacuum pump 26 to remove gas from the reaction chamber 21. After the gaseous pressure in the reaction chamber 21 is sufficiently low, the valve 23 is closed to stop the removal of gas by the vacuum pump 26. After step S130 has finished, the gaseous pressure in the reaction chamber 21 is substantially from 10⁻¹ to 10⁻³ Pascal (Pa).

In step S140, an atomic layer chemical process is implemented. In detail, the valve 23 between the reaction chamber 21 and the first gas tank 24 is opened to allow reaction gas, which includes a reducing gas, to flow from the first gas tank 24 into the reaction chamber 21. The graphene oxide 1, positioned in the reaction chamber 21, contacts the reducing gas. After sufficient reducing gas is supplied in the reaction chamber 21, the valve 23 is closed to stop the supply of reducing gas. The reducing gas, for example, is hydrogen gas (H₂), but the present disclosure is not limited thereto. After that, the reaction chamber 21 is heated up to a temperature of 100° C. to 260° C., and an oxygen stripping reaction of the graphene oxide 1 with the reducing gas of the reaction gas is performed. It is worth noting that the temperature of the oxygen stripping reaction in the present disclosure is not limited by the above. When the oxygen stripping reaction is performed, a reduction reaction of some functional groups in the graphene oxide 1 with the reducing gas (that is, H₂) happens so as to decrease the number of the functional groups containing oxygen in the graphene oxide 1.

The atomic layer chemical process may include one or more cycles of the oxygen stripping reaction. For example, the reducing gas in the reaction chamber 21 reacts with the graphene oxide 1 to perform one cycle of the oxygen stripping reaction. After the one cycle of the oxygen stripping reaction is completed, the valve 23 is opened again to supply new reducing gas into the reaction chamber 21 from the first gas tank 24. The new reducing gas in the reaction chamber 21 reacts with the graphene oxide 1 to perform another cycle of the oxygen stripping reaction. The reduction reaction of the graphene oxide 1 with the reducing gas happens repeatedly to perform multiple cycles of the oxygen stripping reaction. In this embodiment, the atomic layer chemical process includes 10 or more cycles of the oxygen stripping reaction. It is worth noting that the number of cycles of the oxygen stripping reaction in the present disclosure is not limited by the above.

In this embodiment, the reaction gas stored in the first gas tank 24 is a gas mixture of reducing gas and inert gas. For example, the reaction gas is a gas mixture of hydrogen gas and argon (Ar) gas or a gas mixture of hydrogen gas and nitrogen (N₂) gas. Moreover, the gas mixture includes 95 vol % (percentage by volume) of reducing gas and 5 vol % of inert gas in this embodiment, so that it is favorable for preventing an overly fast oxygen stripping reaction of the graphene oxide 1 with the reducing gas, thereby reducing the danger of reactions in step S140. The present disclosure is not limited to the gas stored in the first gas tank 24. In some embodiments, high purity reducing gas is stored in the first gas tank 24; for example, the reaction gas includes more than 99.995 vol % of the reducing gas.

Furthermore, in each cycle of the oxygen stripping reaction, a ratio of the mass of the graphene oxide 1 to a volume of the reducing gas in the reaction chamber 21 is from 0.1 g/mL to 0.5 g/mL; preferably, the ratio is from 0.1 g/mL to 0.33 g/mL. For example, the mass of the graphene oxide 1 is 2 g, and the volume of the reducing gas in the reaction chamber 21 is 20 milliliters (mL). Therefore, it is favorable for maintaining sufficient reducing gas in the reaction chamber 21 to react with the graphene oxide 1 in every cycle of the oxygen stripping reaction, and thus the reaction rate at every part of the graphene oxide 1 is uniform to cause a proper distribution of the functional groups containing oxygen in the graphene oxide 1.

In step S150, the inert gas is supplied in the reaction chamber to contact the graphene oxide. In detail, the valve 23 between the reaction chamber 21 and the second gas tank 25 is opened to allow inert gas (argon gas or nitrogen gas) to flow from the second gas tank 25 into the reaction chamber 21 through the pipe system 22. The inert gas dilutes residual reducing gas in the reaction chamber 21 so as to stop the oxygen stripping reaction.

In step S160, the reaction chamber of the atomic layer deposition equipment is vacuumed again. The valve 23 between the reaction chamber 21 and the vacuum pump 26 is opened again to remove residual gas in the reaction chamber 21 by the vacuum pump 26.

The following specific embodiments are provided for further describing the present disclosure.

### The 1st Embodiment Through the 5th Embodiment

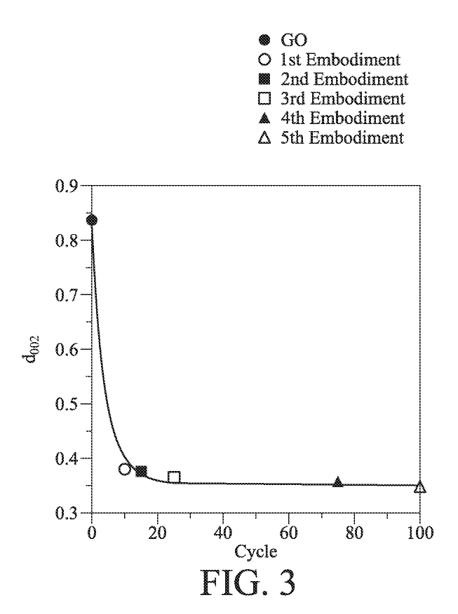

1.0 g of a graphene oxide powder (marked “GO” in FIG. 3 through FIG. 8) is prepared by Hummers method. The average particle size of the graphene oxide powder is from 0.01 millimeters (mm) to 0.03 mm. An oxygen-carbon atomic ratio (0/C ratio) of the graphene oxide powder is 38.3%, and a band gap of the graphene oxide powder is 2.62 electron volts (eV).

The graphene oxide powder is positioned into the reaction chamber 21 of the atomic layer deposition equipment 2 in FIG. 1, and the gaseous pressure in the reaction chamber 21 is decreased to 10⁻³ Pa for the forthcoming atomic layer chemical process. Then, a gas mixture including 95 vol % of hydrogen gas and 5 vol % of nitrogen gas is supplied into the reaction chamber 21 with a flow rate of 300 sccm for 10 seconds. The graphene oxide powder and the gas mixture are heated up to 200° C., and the graphene oxide powder reacts with the gas mixture for 30 seconds to perform one cycle of the oxygen stripping reaction. The gas mixture of hydrogen gas and nitrogen gas may be supplied into the reaction chamber 21 repeatedly to perform multiple cycles of the oxygen stripping reaction. The cycles of oxygen stripping reaction in the 1st embodiment through the 5th embodiment are shown in Table I.

After the atomic layer chemical process (oxygen stripping reaction) is completed, high purity nitrogen gas is supplied into the reaction chamber 21 to dilute residual hydrogen gas, and the residual gas in the reaction chamber 21 is removed by the vacuumed pump 26.

TABLE I

| Embodiment | 1st | 2nd | 3rd | 4th | 5th |
|---|---|---|---|---|---|
| Cycles of oxygen | 10 | 15 | 25 | 75 | 100 |
| stripping reaction | | | | | |

FIG. 3 is a chart of the interlayer distance between each adjacent graphene layer in a graphene oxide, which is treated by the method in FIG. 2, versus cycles of oxygen stripping reaction. With the increase of the cycles of oxygen stripping reaction, the number of the functional groups containing oxygen in the graphene oxide powder is decreased, and thus the interlayer distance (d₀₀₂) between each adjacent graphene layer becomes smaller. Specifically, among the initial 10 cycles, the decrease of the interlayer distance is more noticeable. For the graphene oxide powder, the interlayer distance between each adjacent graphene layer is 0.84 nanometers (nm) before any oxygen stripping reaction is performed. After 10 cycles of the oxygen stripping reaction are performed continuously, the interlayer distance between each adjacent graphene layer is 0.39 nm (the 1st embodiment). After 15 cycles of the oxygen stripping reaction are performed continuously, the interlayer distance between each adjacent graphene layer is 0.38 nm (the 2nd embodiment). After 25 cycles of the oxygen stripping reaction are performed continuously, the interlayer distance between each adjacent graphene layer is 0.37 nm (the 3rd embodiment). After 75 cycles of the oxygen stripping reaction are performed continuously, the interlayer distance between each adjacent graphene layer is 0.36 nm (the 4th embodiment). After 100 cycles of the oxygen stripping reaction are performed continuously, the interlayer distance between each adjacent graphene layer is 0.35 nm (the 5th embodiment).

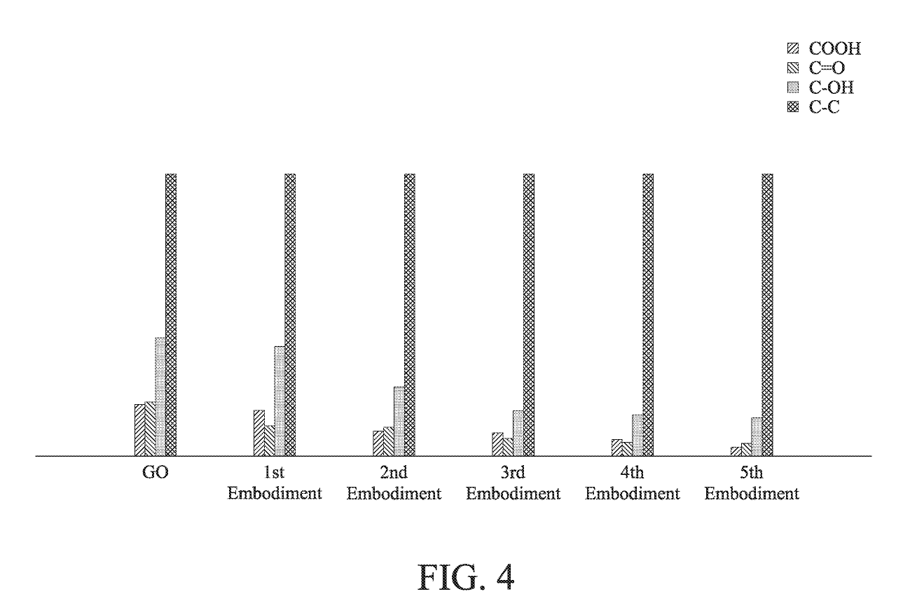

FIG. 4 is a chart of the number of functional groups containing oxygen in the graphene oxide, which is treated by the method in FIG. 2, versus cycles of oxygen stripping reaction. The number of the hydroxyl groups (C—OH), the carbonyl groups (C═O) and the carboxyl groups (COOH) and the carbon bonds (C—C) in the graphene oxide powder are shown in FIG. 4. Among the initial 10 cycles of the oxygen stripping reaction, the number of the carbonyl groups decreased significantly, which means the hydrogen gas mainly reacts with the carbonyl groups. Among 11 to 25 cycles of the oxygen stripping reaction, the hydrogen gas mainly reacts with the hydroxyl groups and the carboxyl groups. Among 26 to 100 cycles of the oxygen stripping reaction, the hydrogen gas reacts with all types of functional groups equally.

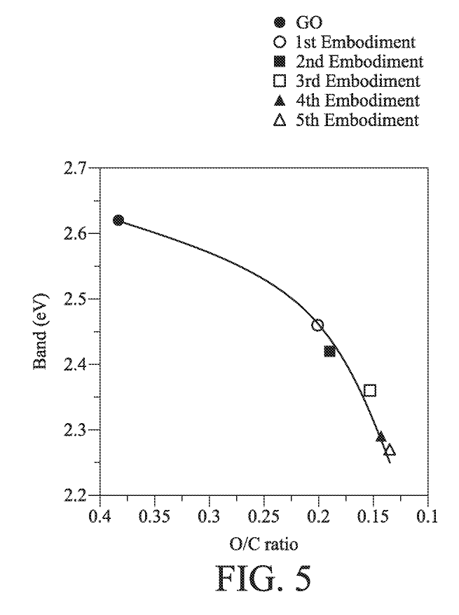

FIG. 5 is a chart of the band gap of the graphene oxide, which is treated by the method in FIG. 2, versus the oxygen-carbon atomic ratio of the graphene oxide. After 10 cycles of the oxygen stripping reaction are performed continuously, the O/C ratio of the graphene oxide powder is 20.1%, and the band gap of the graphene oxide powder is 2.46 eV (the 1st embodiment). After 15 cycles of the oxygen stripping reaction are performed continuously, the O/C ratio of the graphene oxide powder is 19.0%, and the band gap of the graphene oxide powder is 2.42 eV (the 2nd embodiment). After 25 cycles of the oxygen stripping reaction are performed continuously, the O/C ratio of the graphene oxide powder is 15.3%, and the band gap of the graphene oxide powder is 2.37 eV (the 3rd embodiment). After 75 cycles of the oxygen stripping reaction are performed continuously, the O/C ratio of the graphene oxide powder is 14.3%, and the band gap of the graphene oxide powder is 2.29 eV (the 4th embodiment). After 100 cycles of the oxygen stripping reaction are performed continuously, the O/C ratio of the graphene oxide powder is 13.5%, and the band gap of the graphene oxide powder is 2.26 eV (the 5th embodiment).

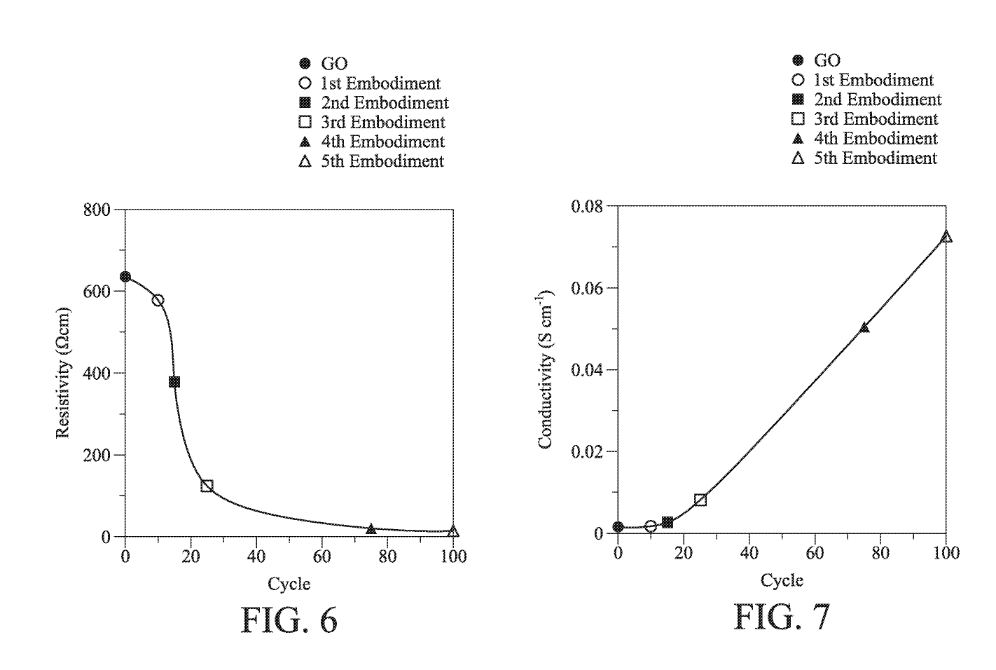

FIG. 6 is a chart of the electrical resistivity of the graphene oxide, which is treated by the method in FIG. 2, versus cycles of oxygen stripping reaction. The electrical resistivity of the graphene oxide powder is 630.0 ohm centimeters (Ω·cm) before any oxygen stripping reaction is performed. After 10 cycles of the oxygen stripping reaction are performed continuously, the electrical resistivity of the graphene oxide powder is 590.0 Ω·cm (the 1st embodiment). After 15 cycles of the oxygen stripping reaction are performed continuously, the electrical resistivity of the graphene oxide powder is 380.0 Ω·cm (the 2nd embodiment). After 25 cycles of the oxygen stripping reaction are performed continuously, the electrical resistivity of the graphene oxide powder is 130.0 Ω·cm (the 3rd embodiment). After 75 cycles of the oxygen stripping reaction are performed continuously, the electrical resistivity of the graphene oxide powder is 30.0 Ω·cm (the 4th embodiment). After 100 cycles of the oxygen stripping reaction are performed continuously, the electrical resistivity of the graphene oxide powder is 15.0 Ω·cm (the 5th embodiment).

FIG. 7 is a chart of the electrical conductivity of the graphene oxide, which is treated by the method in FIG. 2, versus cycles of oxygen stripping reaction. The electrical conductivity of the graphene oxide powder is 0.001 siemens/centimeter (S·cm⁻¹) before any oxygen stripping reaction is performed. After 10 cycles of the oxygen stripping reaction are performed continuously, the electrical conductivity of the graphene oxide powder is 0.002 S·cm⁻¹ (the 1st embodiment). After 15 cycles of the oxygen stripping reaction are performed continuously, the electrical conductivity of the graphene oxide powder is 0.003 S·cm⁻¹ (the 2nd embodiment). After 25 cycles of the oxygen stripping reaction are performed continuously, the electrical conductivity of the graphene oxide powder is 0.009 S·cm⁻¹ (the 3rd embodiment). After 75 cycles of the oxygen stripping reaction are performed continuously, the electrical conductivity of the graphene oxide powder is 0.051 S·cm⁻¹ (the 4th embodiment). After 100 cycles of the oxygen stripping reaction are performed continuously, the electrical conductivity of the graphene oxide powder is 0.073 S·cm⁻¹ (the 5th embodiment). As shown in FIG. 7, the increase of the electrical conductivity is more noticeable after the continuous 15 cycles of the oxygen stripping reaction.

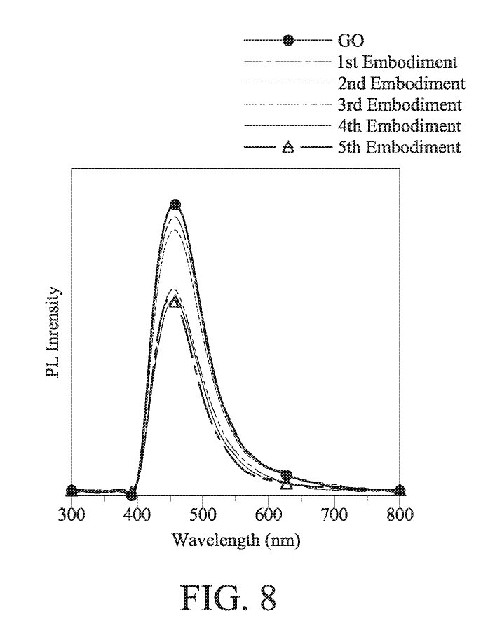

FIG. 8 is a chart showing intensity and wavelength of the photoluminescence response of the graphene oxide which is treated by the method in FIG. 2. The graphene oxide powder, which has reacted with hydrogen gas, can be sieved and screened into nano-scaled graphene oxide quantum dots in the range of 3 nm to 6 nm, and then spread into distilled water. The graphene oxide quantum dots suspended in distilled water is irradiated by a UV light at a wavelength of 340 nm so as to make the graphene oxide quantum dots emit photoluminescence. As shown in FIG. 8, with the increase of the cycles of oxygen stripping reaction, the intensity of the photoluminescence is decreased gradually. In detail, after 100 cycles of the oxygen stripping reaction are performed continuously, the intensity of the photoluminescence is equal to about 60% of the intensity before any oxygen stripping reaction is performed.

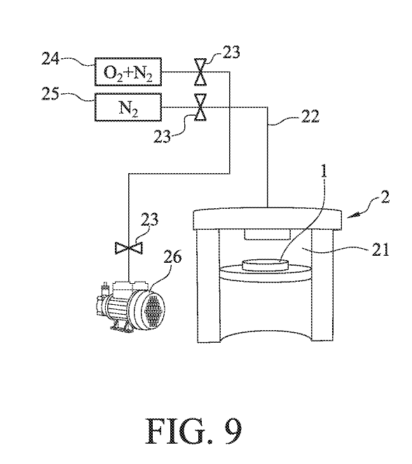

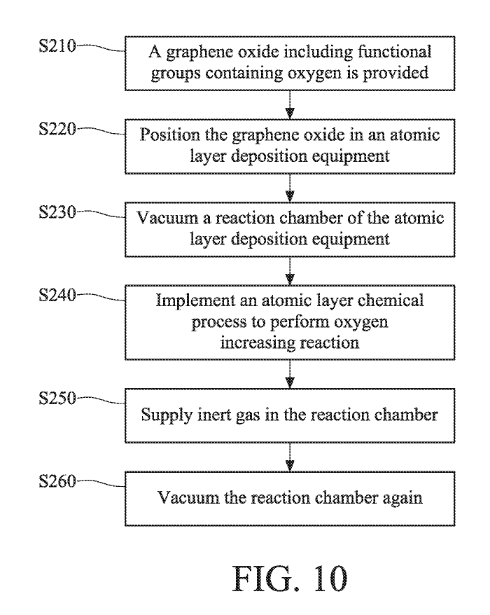

FIG. 1 through FIG. 8 are related to the atomic layer chemical process including oxygen stripping reaction and the optical properties of the graphene oxide after the oxygen stripping reaction is performed, but the present disclosure is not limited thereto. Please refer to FIG. 9 and FIG. 10. FIG. 9 is a schematic view of changing the oxidation level of graphene oxide in atomic layer deposition equipment according to another embodiment of the present disclosure. FIG. 10 is a flowchart of a method of changing the oxidation level of graphene oxide according to another embodiment of the present disclosure.

In this embodiment, a method of changing the oxidation level of graphene oxide is to perform the oxygen increasing reaction of a graphene oxide sheet or a graphene oxide powder in the atomic layer deposition equipment. The method of changing the oxidation level of graphene oxide includes steps S210 to S260.

In step S210, a graphene oxide including functional groups containing oxygen is provided. In this embodiment, a graphene oxide 1 is provided. The graphene oxide 1 is a graphene oxide powder including identical functional groups to the graphene oxide powder described in the aforementioned embodiment.

In step S220, the graphene oxide is positioned in the atomic layer deposition equipment. In this embodiment, the configuration of an atomic layer deposition equipment 2 is identical to the atomic layer deposition equipment described in the aforementioned embodiment.

In step S230, the reaction chamber of the atomic layer deposition equipment is vacuumed. Step S230 is identical to step S130 described in the aforementioned embodiment.

In step S240, an atomic layer chemical process is implemented. In detail, the valve 23 between the reaction chamber 21 and the first gas tank 24 is opened to allow reaction gas, which includes an oxidizing gas, to flow from the first gas tank 24 into the reaction chamber 21. The graphene oxide 1 positioned in the reaction chamber 21 contacts the oxidizing gas. After sufficient oxidizing gas is supplied in the reaction chamber 21, the valve 23 is closed to stop the supply of oxidizing gas. The oxidizing gas, for example, is oxygen gas (O₂), but the present disclosure is not limited thereto. After that, the reaction chamber 21 is heated up to a temperature of 100° C. to 260° C., and an oxygen increasing reaction of the graphene oxide 1 with the oxidizing gas of the reaction gas is performed. It is worth noting that the temperature of the oxygen increasing reaction in the present disclosure is not limited by the above. When the oxygen increasing reaction is performed, an oxidation reaction of some carbons in the graphene oxide 1 with the oxidizing gas (that is, O₂) happens so as to increase the number of the functional groups containing oxygen in the graphene oxide 1.

The atomic layer chemical process may include one or more cycles of the oxygen increasing reaction. For example, the oxidizing gas in the reaction chamber 21 reacts with the graphene oxide 1 to perform one cycle of the oxygen increasing reaction. After the one cycle of the oxygen increasing reaction is completed, the valve 23 is opened again to supply new oxidizing gas into the reaction chamber 21 from the first gas tank 24. The new oxidizing gas in the reaction chamber 21 reacts with the graphene oxide 1 to perform another cycle of the oxygen increasing reaction. The reduction reaction of the graphene oxide 1 with the oxidizing gas happens repeatedly to perform multiple cycles of the oxygen increasing reaction. In this embodiment, the atomic layer chemical process includes 10 or more cycles of the oxygen increasing reaction. It is worth noting that the number of cycles of the oxygen increasing reaction in the present disclosure is not limited by the above.

In this embodiment, the reaction gas stored in the first gas tank 24 is a gas mixture of oxidizing gas and inert gas. For example, the reaction gas is a gas mixture of oxygen gas and argon (Ar) gas or a gas mixture of oxygen gas and nitrogen (N₂) gas. Moreover, the gas mixture includes 95 vol % (percentage by volume) of oxidizing gas and 5 vol % of inert gas in this embodiment. The present disclosure is not limited to the gas stored in the first gas tank 24. In some embodiments, high purity oxidizing gas is stored in the first gas tank 24; for example, the reaction gas includes more than 99.995 vol % of the oxidizing gas. Furthermore, in each cycle of the oxygen increasing reaction, a ratio of the mass of the graphene oxide 1 to a volume of the oxidizing gas in the reaction chamber 21 is from 0.1 (g/mL) to 0.5 (g/mL); preferably, the ratio is from 0.06 (g/mL) to 0.33 (g/mL).

In step S250, the inert gas is supplied in the reaction chamber to contact the graphene oxide. In detail, the valve 23 between the reaction chamber 21 and the second gas tank 25 is opened to allow inert gas (argon gas or nitrogen gas) to flow from the second gas tank 25 into the reaction chamber 21 through the pipe system 22. The inert gas dilutes residual oxidizing gas in the reaction chamber 21 so as to stop the oxygen increasing reaction.

In step S260, the reaction chamber of the atomic layer deposition equipment is vacuumed again. The valve 23 between the reaction chamber 21 and the vacuum pump 26 is opened again to remove residual gas in the reaction chamber 21 by the vacuum pump 26.

The following specific embodiments are provided for further describing the present disclosure.

### The 6th Embodiment Through the 12th Embodiment

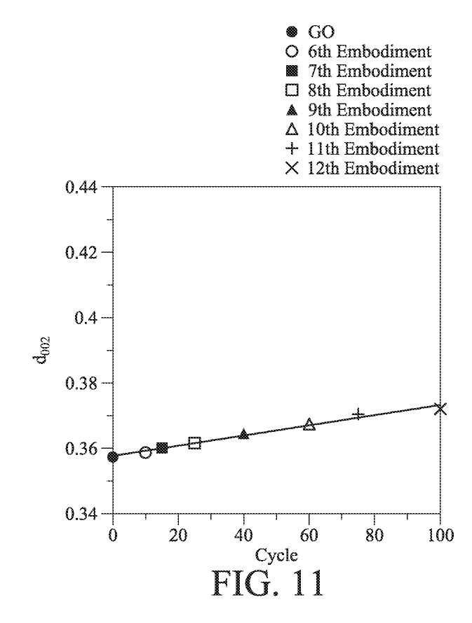

1.0 g of a graphene oxide powder (marked “GO” in FIG. 11 through FIG. 17) is prepared by Hummers method. The average particle size of the graphene oxide powder is from 0.01 mm to 0.03 mm. An O/C ratio of the graphene oxide powder is 15.4%, and a band gap of the graphene oxide powder is 1.77 eV.

The graphene oxide powder is positioned into the reaction chamber 21 of the atomic layer deposition equipment 2 in FIG. 1, and the gaseous pressure in the reaction chamber 21 is decreased to 10⁻³ Pa for the forthcoming atomic layer chemical process. Then, a gas mixture including 95 vol % of oxygen gas and 5 vol % of nitrogen gas is supplied into the reaction chamber 21 with a flow rate of 300 sccm for 10 seconds. The graphene oxide powder and the gas mixture are heated up to 200° C., and the graphene oxide powder reacts with the gas mixture for 30 seconds to perform one cycle of the oxygen increasing reaction. The gas mixture of oxygen gas and nitrogen gas may be supplied into the reaction chamber 21 repeatedly to perform multiple cycles of the oxygen increasing reaction. The cycles of oxygen increasing reaction in the 6th embodiment through the 12th embodiment are shown in Table II.

After the atomic layer chemical process (oxygen increasing reaction) is completed, high purity nitrogen gas is supplied into the reaction chamber 21 to dilute residual oxygen gas, and the residual gas in the reaction chamber 21 is removed by the vacuumed pump 26.

TABLE II

| Embodiment | 6th | 7th | 8th | 9th |
|---|---|---|---|---|
| Cycles of oxygen | 10 | 15 | 25 | 40 |
| increasing reaction | | | | |

| Embodiment | 10th | 11th | 12th |
|---|---|---|---|
| Cycles of oxygen | 60 | 75 | 100 |
| increasing reaction | | | |

FIG. 11 is a chart of the interlayer distance between each adjacent graphene layer in a graphene oxide, which is treated by the method in FIG. 10, versus cycles of oxygen increasing reaction. With the increase of the cycles of oxygen increasing reaction, the number of the functional groups containing oxygen in the graphene oxide powder is increased, and thus the interlayer distance (d₀₀₂) between each adjacent graphene layer become larger. For the graphene oxide powder, the interlayer distance between each adjacent graphene layer is 0.357 nm before any oxygen increasing reaction is performed. After 10 cycles of the oxygen increasing reaction are performed continuously, the interlayer distance between each adjacent graphene layer is 0.358 nm (the 6th embodiment). After 15 cycles of the oxygen increasing reaction are performed continuously, the interlayer distance between each adjacent graphene layer is 0.360 nm (the 7th embodiment). After 25 cycles of the oxygen increasing reaction are performed continuously, the interlayer distance between each adjacent graphene layer is 0.362 nm (the 8th embodiment). After 40 cycles of the oxygen increasing reaction are performed continuously, the interlayer distance between each adjacent graphene layer is 0.364 nm (the 9th embodiment). After 60 cycles of the oxygen increasing reaction are performed continuously, the interlayer distance between each adjacent graphene layer is 0.366 nm (the 10th embodiment). After 75 cycles of the oxygen increasing reaction are performed continuously, the interlayer distance between each adjacent graphene layer is 0.370 nm (the 11th embodiment). After 100 cycles of the oxygen increasing reaction are performed continuously, the interlayer distance between each adjacent graphene layer is 0.372 nm (the 12th embodiment).

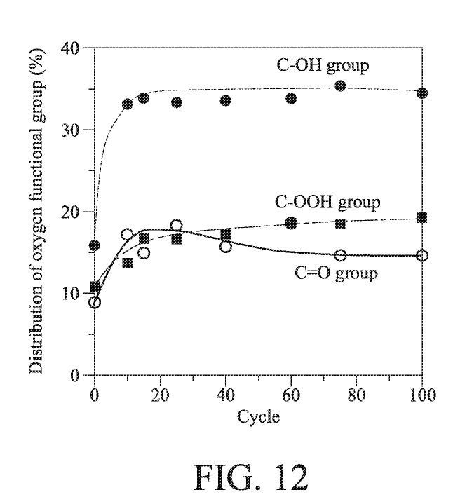

FIG. 12 is a chart of the number of functional groups containing oxygen in the graphene oxide, which is treated by the method in FIG. 10, versus cycles of oxygen increasing reaction. The number of the hydroxyl groups (C—OH), the carbonyl groups (C═O) and the carboxyl groups (COOH) and the carbon bonds (C—C) in the graphene oxide powder are shown in FIG. 4. Among initial 25 cycles of the oxygen increasing reaction, the oxygen gas reacts with all types of functional group equally. Among 26 to 100 cycles of the oxygen increasing reaction, some carbonyl groups are transformed into hydroxyl groups or carboxyl groups so as to decrease the number of carbonyl groups and increase the number of carbonyl groups and carboxyl groups.

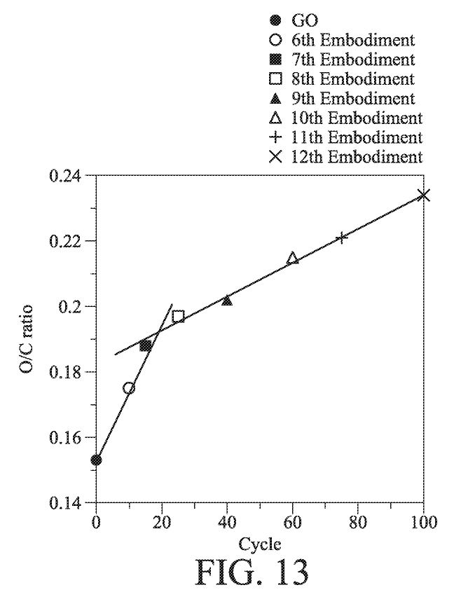

FIG. 13 is a chart of the oxygen-carbon atomic ratio of the graphene oxide, which is treated by the method in FIG. 10, versus cycles of oxygen increasing reaction. Among initial 20 cycles of the oxygen increasing reaction, the O/C ratio of the graphene oxide powder is increased more in each cycle. Among 21 to 100 cycles of the oxygen increasing reaction, the O/C ratio of the graphene oxide powder is increased less in each cycle. Specifically, the O/C ratio of the graphene oxide powder is increased by 0.23% in each of the initial 20 cycles, and the O/C ratio is increased by 0.054% in each of the 21 to 100 cycles.

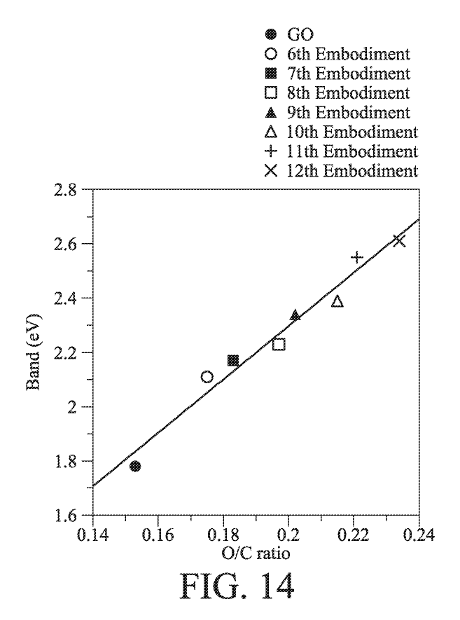

FIG. 14 is a chart of the band gap of the graphene oxide, which is treated by the method in FIG. 10, versus the oxygen-carbon atomic ratio of the graphene oxide. After 10 cycles of the oxygen increasing reaction are performed continuously, the O/C ratio of the graphene oxide powder is 17.3%, and the band gap of the graphene oxide powder is 2.12 eV (the 6th embodiment). After 15 cycles of the oxygen increasing reaction are performed continuously, the O/C ratio of the graphene oxide powder is 18.4%, and the band gap of the graphene oxide powder is 2.18 eV (the 7th embodiment). After 25 cycles of the oxygen increasing reaction are performed continuously, the O/C ratio of the graphene oxide powder is 19.8%, and the band gap of the graphene oxide powder is 2.23 eV (the 8th embodiment). After 40 cycles of the oxygen increasing reaction are performed continuously, the O/C ratio of the graphene oxide powder is 20.2%, and the band gap of the graphene oxide powder is 2.34 eV (the 9th embodiment). After 60 cycles of the oxygen increasing reaction are performed continuously, the O/C ratio of the graphene oxide powder is 21.5%, and the band gap of the graphene oxide powder is 2.39 eV (the 10th embodiment). After 75 cycles of the oxygen increasing reaction are performed continuously, the O/C ratio of the graphene oxide powder is 22.0%, and the band gap of the graphene oxide powder is 2.55 eV (the 11th embodiment). After 100 cycles of the oxygen increasing reaction are performed continuously, the O/C ratio of the graphene oxide powder is 23.5%, and the band gap of the graphene oxide powder is 2.61 eV (the 12th embodiment).

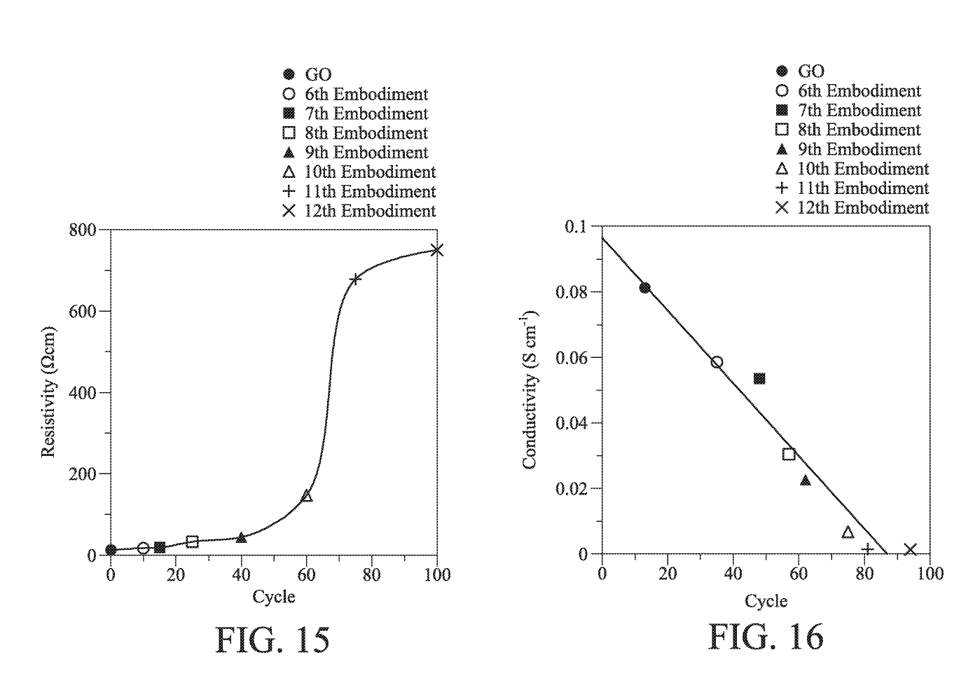

FIG. 15 is a chart of the electrical resistivity of the graphene oxide, which is treated by the method in FIG. 10, versus cycles of oxygen increasing reaction. The electrical resistivity of the graphene oxide powder is 20.0 Ω·cm before any oxygen increasing reaction is performed. After 10 cycles of the oxygen increasing reaction are performed continuously, the electrical resistivity of the graphene oxide powder is 28.0 Ω·cm (the 6th embodiment). After 15 cycles of the oxygen increasing reaction are performed continuously, the electrical resistivity of the graphene oxide powder is 32.0 Ω·cm (the 7th embodiment). After 25 cycles of the oxygen increasing reaction are performed continuously, the electrical resistivity of the graphene oxide powder is 46.0 Ω·cm (the 8th embodiment). After 40 cycles of the oxygen increasing reaction are performed continuously, the electrical resistivity of the graphene oxide powder is 50.0 Ω·cm (the 9th embodiment). After 60 cycles of the oxygen increasing reaction are performed continuously, the electrical resistivity of the graphene oxide powder is 145.0 Ω·cm (the 10th embodiment). After 75 cycles of the oxygen increasing reaction are performed continuously, the electrical resistivity of the graphene oxide powder is 688.0 Ω·cm (the 11th embodiment). After 100 cycles of the oxygen increasing reaction are performed continuously, the electrical resistivity of the graphene oxide powder is 750.0 Ω·cm (the 12th embodiment). As shown in FIG. 15, the increase of the electrical resistivity is more noticeable after the continuous 60 cycles of the oxygen increasing reaction.

FIG. 16 is a chart of the electrical conductivity of the graphene oxide, which is treated by the method in FIG. 10, versus cycles of oxygen increasing reaction. The electrical conductivity of the graphene oxide powder is 0.081 S·cm⁻¹ before any oxygen increasing reaction is performed. After 10 cycles of the oxygen increasing reaction are performed continuously, the electrical conductivity of the graphene oxide powder is 0.059 S·cm⁻¹ (the 6th embodiment). After 15 cycles of the oxygen increasing reaction are performed continuously, the electrical conductivity of the graphene oxide powder is 0.055 S·cm⁻¹ (the 7th embodiment). After 25 cycles of the oxygen increasing reaction are performed continuously, the electrical conductivity of the graphene oxide powder is 0.029 S·cm⁻¹ (the 8th embodiment). After 40 cycles of the oxygen increasing reaction are performed continuously, the electrical conductivity of the graphene oxide powder is 0.022 S·cm⁻¹ (the 9th embodiment). After 60 cycles of the oxygen increasing reaction are performed continuously, the electrical conductivity of the graphene oxide powder is 0.007 S·cm⁻¹ (the 10th embodiment). After 75 cycles of the oxygen increasing reaction are performed continuously, the electrical conductivity of the graphene oxide powder is 0.003 S·cm⁻¹ (the 11th embodiment). After 100 cycles of the oxygen increasing reaction are performed continuously, the electrical conductivity of the graphene oxide powder is 0.002 S·cm⁻¹ (the 12th embodiment).

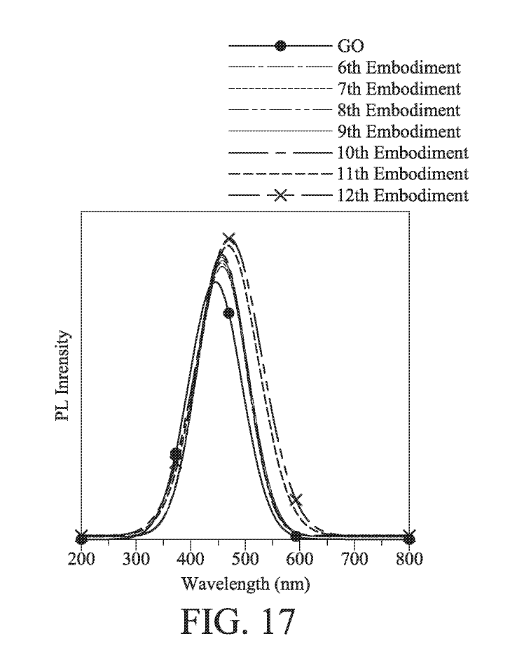

FIG. 17 is a chart showing intensity and wavelength of the photoluminescence response of the graphene oxide which is treated by the method in FIG. 10. The graphene oxide powder, which has reacted with oxygen gas, can be sieved and screened into nano-scaled graphene oxide quantum dots in the range of 3 nm to 6 nm, and then spread into distilled water. The graphene oxide quantum dots suspended in distilled water is irradiated by a UV light at a wavelength of 340 nm so as to make the graphene oxide quantum dots emit photoluminescence. As shown in FIG. 17, with the increase of the cycles of oxygen increasing reaction, the intensity of the photoluminescence is increased gradually. In detail, After 100 cycles of the oxygen increasing reaction are performed continuously, the intensity of the photoluminescence is equal to about 120% of the intensity before any oxygen increasing reaction is performed.

According to the present disclosure, the band gap of graphene oxide can be analyzed by an electrochemical device at ambient temperature, and the electrochemical device includes, for example, Ag/AgCl and Pt respectively served as reference and counter electrode, and CuSO₄ served as an electrolyte. Both the number of functional groups containing oxygen and the type thereof in the graphene oxide can be analyzed by X-ray photoelectron spectroscopy (XPS), and both the interlayer distance between each adjacent graphene layer and the O/C ratio can be analyzed by X-ray diffraction (XRD). Both the electrical resistivity and the electrical conductivity of graphene oxide can be analyzed by a four-probe resistance measurement. The intensity of photoluminescence response can be analyzed by a fluorescence spectrophotometer.

According to the present disclosure, the atomic layer chemical process includes both the oxygen stripping reaction and the oxygen increasing reaction in a single embodiment. For example, the atomic layer deposition equipment of FIG. 1 can further include a third gas tank configured to store a reaction gas including oxidizing gas. Thus, several cycles of the oxygen increasing reaction may be performed after several cycles of the oxygen stripping reaction so as to fine-tune the number of functional groups containing oxygen.

According to the present disclosure, the cycles of the oxygen stripping reaction or the oxygen increasing reaction can be performed continuously. For example, when 10 cycles of the oxygen stripping reaction are performed continuously, it is indicated that there is not an oxygen increasing reaction interposed between any two of the 10 cycles of the oxygen stripping reaction. Similarly, when 10 cycles of the oxygen increasing reaction are performed continuously, it is indicated that there is not an oxygen stripping reaction interposed between any two of the 10 cycles of the oxygen increasing reaction.

According to the present disclosure, the method of changing the oxidation level is favorable for changing the O/C ratio in the graphene oxide so as to change the electrical properties of the graphene oxide, such as band gap, electrical resistivity, and conductivity. An application is a graphene wafer including graphene oxide treated by the method of changing oxidation level of the present disclosure.

In addition, the method of changing oxidation level is also favorable for changing the intensity of the photoluminescence response of the graphene oxide quantum dots. An application is an optical coating including graphene oxide quantum dots treated by the method of changing oxidation level of the present disclosure. In order to form an optical coating on a surface of the substrate, the graphene oxide quantum dots can be sprayed on the substrate; or, a mixture of graphene oxide quantum dots and gel can be spread on the substrate.

According to the present disclosure, the number of functional groups containing oxygen (oxidation level) in the graphene oxide is changeable by the oxygen stripping reaction and the oxygen increasing reaction performed by atomic layer deposition equipment. Therefore, the O/C ratio of the graphene oxide is determined according to the cycles of oxygen stripping reaction as well as the cycles of oxygen increasing reaction, thereby obtaining required physical and chemical properties such as band gap, resistivity, conductivity and intensity of photoluminescence response. The method of changing the oxidation level of graphene oxide of the present disclosure is widely applicable to various applications including the manufactures of graphene wafer and optical coating.

The embodiments are chosen and described in order to best explain the principles of the present disclosure and its practical applications, to thereby enable others skilled in the art best utilize the present disclosure and various embodiments with various modifications as are suited to the particular use being contemplated. It is intended that the scope of the present disclosure is defined by the following claims and their equivalents.

What is claimed is:

1. A method of changing an oxidation level of graphene oxide, comprising:
providing a graphene oxide comprising functional groups containing oxygen; and
implementing an atomic layer chemical process to perform an oxygen stripping reaction or an oxygen increasing reaction of the graphene oxide with a reaction gas, and the atomic layer chemical process comprising 10 or more cycles of the oxygen stripping reaction or 10 or more cycles of the oxygen increasing reaction.

2. The method according to claim 1, wherein the 10 or more cycles of the oxygen stripping reaction are performed continuously, and the 10 or more cycles of the oxygen increasing reaction are performed continuously.

3. The method according to claim 1, wherein the atomic layer chemical process comprises 15 or more cycles of the oxygen stripping reaction.

4. The method according to claim 1, wherein the atomic layer chemical process comprises 60 or more cycles of the oxygen increasing reaction.

5. The method according to claim 1, wherein the oxygen stripping reaction and the oxygen increasing reaction are performed at a temperature of 100° C. to 260° C.

6. The method according to claim 1, wherein the reaction gas is oxidizing gas or reducing gas, and a ratio of mass of the graphene oxide to volume of the reaction gas is from 0.1 g/mL to 0.5 g/mL.

7. The method according to claim 1, wherein the reaction gas is a gas mixture of oxidizing gas and inert gas or a gas mixture of reducing gas and inert gas.

8. The method according to claim 7, wherein the gas mixture comprises 95 vol % of oxidizing gas or reducing gas and 5 vol % of inert gas.

9. A wafer comprising graphene oxide treated by the method of changing the oxidation level of graphene oxide according to claim 1.

10. An optical coating comprising graphene oxide quantum dots treated by the method of changing the oxidation level of graphene oxide according to claim 1.
